(19) United States
(12) Patent Application Publication
(10) Pub. No.: US 2002/0086190 A1
(43) Pub. Date: Jul. 4, 2002

(54) Thin film of aluminate including rare earth elements, method of producing same, and light-accumulation optical element

(75) Inventor: Tomoko Miyaura, Habikino-Shi (JP)

Correspondence Address: SIDLEY AUSTIN BROWN & WOOD LLP, 717 NORTH HARWOOD, SUITE 3400, DALLAS, TX, 75201, US

(73) Assignee: MINOLTA CO., LTD.

(21) Appl. No.: 09/978,887

(22) Filed: Oct. 17, 2001

(30) Foreign Application Priority Data
Nov. 13, 2000 (JP) 2000-344655

(51) Int. Cl. B32B 19/00; C23C 14/32

(52) U.S. Cl. 428/702; 428/699; 428/697; 204/192.26

(57) ABSTRACT

The purpose of the invention is to provide a light-accumulation material having high emission intensity, and a simple method to produce such material. This purpose is fulfilled by a complex compound including only rare earth element and aluminate as a main component formed as a thin film which is used as a light-accumulation material. The thin film can be manufactured on a substrate by RF magnetron spattering using the aluminate and rare earth element compound as raw material. Spattering gas may be argon, or argon including oxygen or ozone. After the thin film is formed, the thin film may be heated in the presence of oxygen to increase the oxygen within the thin film.

### RELATED APPLICATION

This application is based on Patent Application No. 2000-344655 filed in Japan, the entire content of which is hereby incorporated by reference.

### BACKGROUND OF THE INVENTION

1. Field of the Invention

The present invention relates to light-accumulation optical material including rare earth elements, and a light-accumulation optical element using same.

2. Description of the Related Art

Light-accumulation materials which absorb light as energy and release absorbed energy as light after light reception ends are conventionally used as luminous paint for marking and the like. A representative light-accumulation material is ceramic aluminate including a small amount of rare earth element. Light-accumulation ceramics manifest a light-accumulation phenomenon wherein part of the electrons of a rare earth element additive absorb energy mainly from ultraviolet to near ultraviolet light and become excited, and release energy as light in the visible range when returning to a base level.

Methods for producing light-accumulation ceramics are disclosed in Japanese Laid-Open Patent Nos. H7-223861, H9-143464, H10-36833, H11-61114 and the like. All of these disclosures are based on general manufacturing methods for ceramics, and include a process for mixing and sintering rare earth element compounds in aluminate. Accordingly, the obtained light-accumulation ceramic is bulk or sheet-like, and is powdered or granulated by pulverization.

Powdered or granulated light-accumulation ceramics are generally mixed with paints and applied to the surface of an object. The grains or powder are recombined at high temperature and high pressure, or are formed in sheets solid sheets using transparent resin depending on the purpose.

In recent years, it has been proposed to use light-accumulation ceramic as a light source for a liquid crystal display to reduce power consumption. For example, Japanese Laid-Open Patent No. H8-152622 discloses a structure wherein a sheet painted with light-accumulation ceramic is arranged behind a liquid crystal panel, and Japanese Laid-Open Patent No. H8-262439 discloses a structure wherein a layer including powder of a light-accumulation ceramic is arranged behind a liquid crystal panel, and a light guide is disposed around the liquid crystal panel to direct light to this layer. In these structures, the light-accumulation ceramic, which stores the energy of external light, emits light which is used as a backlight.

Light-accumulation ceramic is not very suitable for use as an illumination light source, due to the low intensity of the emitted light. When the light emitted from a light-accumulation ceramic is used as a backlight as described above, power consumption can be reduced to some degree, however, in a dark environment, a projection image of practical brightness cannot be provided unless another light source is used.

There are a number of causes for the low intensity of the light emitted from light-accumulation ceramics. First, since it is granular or powder-like, there are air gaps between the grains and powder particles which reduce density, and the percentage of that part which participates in the emission of light among all the material is reduced. Furthermore, since the grains and powder are not transparent, it is difficult for external light to attain the interior area, and the part participating in light emission is limited to the surface part. In addition, since a solid-state aluminate and solid-state rare earth element compound are mixed, it is difficult to attain uniform composition, and parts of the material may not contain rare earth element.

These problems reduce the light-accumulation efficiency, i.e., light energy absorption efficiency. Furthermore, the low transparency of the grains and powder also reduces efficient use of the emitted light. The emitted light is randomly reflected, and emerges to the exterior with difficulty. Although transparency is increased when the resin is hardened and sheet-like, the intensity of the emitted light is rather low due to small absolute amount of light-accumulation ceramic content.

Air gaps may be reduced by recombination the grains and powder under high temperature and pressure. However, not all air gaps can be eliminated. Transparency also may be increased by improving the crystal properties by high-temperature and high-pressure processing, but this is limited to semi-transparency. The uniformity of composition can be improved by mixing for a long time, however, there is normally no limit to the uniformity of composition attained by long mixing, and this readily results in variations in uniformity from lot to lot. Therefore, reduced production efficiency cannot be avoided.

### SUMMARY OF THE INVENTION

In view of the previously described disadvantages, an object of the present invention is to provide a light-accumulation material capable of emitting light of high intensity, a method of producing such material, and a light-accumulation optical element suitable for use as an illumination light source.

The present invention attains these objects by providing a thin film essentially consisting of an aluminate containing rare earth element. As for a thin film, it is desirable that it is the thickness more than a wavelength for light accumulating, and is the thickness which can maintain the form as a thin film. From such point of view, the thickness of the film is from 0.4 μm to 0 μm. It is specifically desirable that the rare earth element is contained from about 0.5 mol % to 10 mol % in the thin film. Furthermore, it is desirable that the rare earth elements of this percentage are uniformly contained in the entire face of the thin film.

A thin film is a solid of densely packed atoms, groups of atoms, or molecules without aggregation of grains and powder well-known in the field of semiconductor art. Accordingly, there are no air gaps, there is highly uniform composition, and transparency also is high. That is, the thin film of the present invention is a light-accumulation material which emits light of high intensity unaccompanied by the aforesaid disadvantages which are inescapable in ceramics. There are no restrictions on the concentration of rare earth elements, however, a concentration of rare earth elements of several percent or less is adequate as the light-accumulation material.

Any among SrAl₂O₄, Sr₄Al₁₄O₂₅, CaAl₂O₄ may be used as the aluminate, and any among Dy and Nd may be used with Eu as earth elements. These aluminates are thin films having a high degree of transparency, and these rare earth elements are suitable for absorbing light energy, and releasing this energy as visible light. The Eu functions as activator, and Dy and Nd function as coactivators.

In the present invention, the light-accumulation optical element is provided with this thin film, and a substrate supporting the thin film. This thin film has the characteristic of emitting light of high intensity, but since it is a thin film it is difficult to handle independently. The thin film becomes easy to handle when supported on a substrate, and the production efficiency is high as a light-accumulation optical element. The substrate used when manufacturing the thin film may be used directly. The substrate may be transparent or non-transparent.

These objects are attained by the present invention which provides a raw material including aluminate and rare earth element on a magnetron cathode, placing a substrate opposite the raw material, moving the raw material component onto the substrate via RF magnetron spattering to produce a thin film having as a main component an aluminate including rare earth element on a substrate.

Various thin film manufacturing methods have been established in semiconductor art, and it is anticipated that the thin film of aluminate including rare earth element may be manufactured using any of these methods. However, not just any manufacturing method can be used. For example, in the DC magnetron spattering method, discharge does not originate in the aluminate, and a film is not formed. Furthermore, in the vacuum deposition method, although an aluminate thin film may be formed, this thin film does not contain the rare earth element.

The present invention discovered suitable methods for manufacturing a thin film of aluminate including rare earth element among various well-known methods. The foremost method is the use of the RF magnetron spattering method to manufacture a thin film having uniformly dispersed rare earth element. Moreover, this method allows the concentration of rare earth element to be easily adjusted.

Any among SrAl₂O₄, Sr₄Al₁₄O₂₅, CaAl₂O₄, and any among Dy₂O₃ and Nd₂O₃ may be used with Eu₂O₃ as raw materials. A thin film emitting high intensity light can be obtained.

A mixture of aluminate powder and rare earth element powder may be used as raw material, and a sintered plate of aluminate, and pellets of rare earth element compound may be used as raw material. That is, either a powder method or pellet method may be used.

RF magnetron spattering may be performed with the substrate maintained within a temperature range of 200° C. or higher but lower than 700° C. A thin film of uniformly dispersed constituents may be obtained in a relatively short time by maintaining the substrate temperature within this range.

RF magnetron spattering also may be performed using argon gas containing 5% or more, but less than 50% oxygen or ozone. The use of argon as a spatter gas is most efficient from the perspective of the film forming speed, however, when spattering using only argon, the oxygen in the thin film may be less than desired component depending on the raw material used. A thin film with inadequate oxygen can be avoided by including 5% or more oxygen or ozone in the argon, and a large reduction in film forming speed can be avoided by using less than 50% oxygen or ozone.

RF magnetron spattering using argon may be performed while oxygen or ozone or ions thereof are supplied near the substrate. Similarly, RF magnetron spattering may be performed using argon gas including oxygen or ozone while oxygen or ozone or ions thereof are supplied near the substrate. In this way it is possible to avoid an oxygen insufficiency in the thin film while maintaining a high film forming speed.

After RF magnetron spattering is performed, the thin film on the substrate also may be heated in an atmosphere including oxygen. A thin film of desired components may be obtained by the supplemental heating process even when there is insufficient oxygen during the film forming process.

The invention itself, together with further objects and attendant advantages, will be best understood by reference to the following detailed description taken in conjunction with the accompanying drawings.

### BRIEF DESCRIPTION OF THE DRAWINGS

FIG. 1 is a schematic cross section view showing thee structure of a light-accumulation optical element obtained by the embodiments of the present invention;

FIG. 2 briefly shows the structure of an RF magnetron spattering device used in the first embodiment;

FIG. 3 shows and example of a target when an aluminate powder and a rare earth element compound powder are used as raw materials;

FIG. 4 shows and example of a target when an aluminate sheet and a rare earth element compound pellets are used as raw materials;

FIG. 5 shows the light emission intensity of a specimen produced by the method of the first embodiment, and a specimen of a reference example;

FIG. 6 briefly shows the structure of an RF magnetron spattering device used n a second embodiment;

FIG. 7 shows the light emission intensity of a specimen produced by the method of the second embodiment, and a specimen of a reference example;

FIG. 8 briefly shows the structure of an RF magnetron spattering device used in a third embodiment;

FIG. 9shows the light emission intensity of a specimen produced by the method of the third embodiment, and a specimen of a reference example; and

FIG. 10riefly shows the structure of an RF magnetron spattering device used in a fourth embodiment;

In the following description, like parts are designated by like reference numbers throughout the several drawings.

### DESCRIPTION OF THE PREFERRED EMBODIMENTS

The embodiments of the present invention are described hereinafter by way of specific examples. In each embodiment, a thin film of a complex compound having a main component of aluminate including rare earth element (i.e., a substance including a plurality of compounds as structural components) is produced on a substrate by RF magnetron spattering. The substrate, on the surface of which is deposited the manufactured thin, film is a light-accumulating optical element.

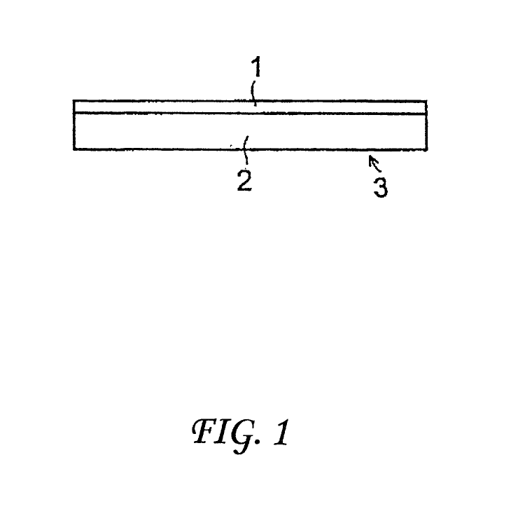

A cross section of the produced light-accumulating optical element is shown schematically in FIG. 1. A light-accumulating optical element 3 simply comprises a transparent thin film 1 of a complex compound including rare earth element and aluminate, and a substrate 2 for supporting the thin film 1. The thickness of the thin film 1 can be freely set by the processing time of RF magnetron spattering, and is easily set at approximately 5 μm or more. The substrate 2 may be transparent, or non-transparent.

A cuttable material may be used as the substrate 2, such that the light-accumulating optical element 3 can be divided by cutting, and each section may be a light-accumulating optical element. The light-accumulating optical element 3 or the divided light-accumulating optical elements may be housed in a protective member to protect the thin film 1. At that time, the protective member may produced using a transparent material, or a window may be provided in part of the protective member, to allow light absorption and release. If a transparent substrate is used as the substrate 2, the protective member may be nontransparent since light may be absorbed from the substrate side and may be released to the substrate side.

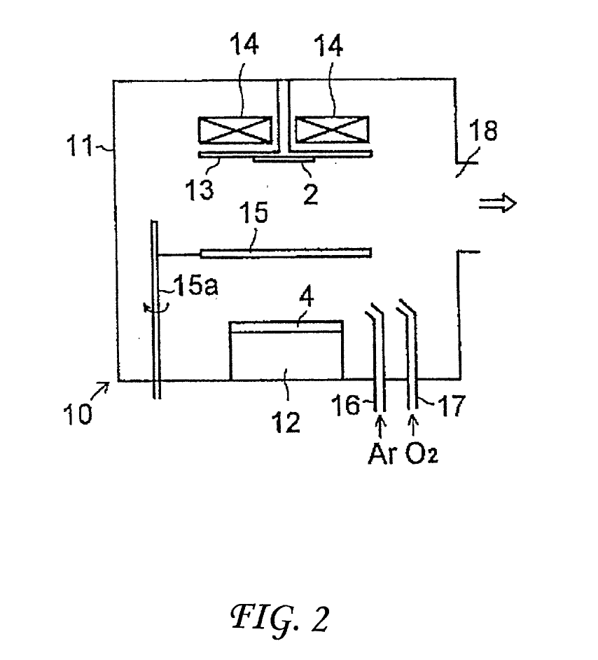

The structure of a RF magnetron spattering device 10 used in the first embodiment is briefly shown in FIG. 2. The RF magnetron spattering device 10 is provided with a vacuum tank 11, and within the vacuum tank 11 are disposed a magnetron cathode 12, substrate holder 13, heaters 14, and shutter 15, and outside the vacuum tank 11 are disposed two gas pipes 16 and 17 near the magnetron cathode 12. An exhaust port 18 is provided in the side wall of the vacuum tank 11, and the gas exhaust port 18 is connected to a vacuum pump (not shown) via a pipe which can be opened and closed.

The magnetron cathode 12 and substrate holder 13 confront one another, and the substrate holder 13 is position above the magnetron cathode 12. A target 4 loaded with the raw material (aluminate including rare earth element) to manufacture the thin film 1 is installed on the top surface of the magnetron cathode 12. The substrate 2 on the surface of which is to be formed the thin film 1 is installed on the bottom surface of the substrate holder 13.

The heaters 14 heat the substrate 2 through the substrate holder 13. The shutter 15 is supported on a rotating shaft 15a, and can be set at an advance position medial to the magnetron cathode 12 and substrate holder 13, and a retracted position separated from between the magnetron cathode 12 and the substrate holder 13. Pipes 16 and 17 supply spattering gas into the vacuum tank 11, and the gas exhaust port 18 removes gas from the vacuum tank 11.

The thin film 1 is manufactured in the manner described below. First, the target 4 loaded with raw material is installed on the magnetron cathode 12, and the substrate 2 is mounted on the substrate holder 13. Then, a temporary vacuum is formed in the vacuum tank 11 by exhausting the air from the gas exhaust port 18, the substrate 2 is heated, and a high frequency (RF) voltage is applied to the magnetron cathode 12 as a small amount of spattering gas is supplied from pipes 16 and 17, and a plasma is generated near the top surface of the cathode 12. In this way spattering is performed, and part of the raw material becomes airborne as atoms, atom groups, or ions. The shutter 15 is retracted at the moment spattering and the temperature of the substrate 2 become stable, and atoms and the like are spattered and deposited on the surface of the substrate 2 so as to form the thin film 1.

The film forming speed is dependent on the spattering conditions, however, a film forming speed of 0.5˜1 μm/hr is possible. Accordingly, a thin film 1 having a thickness of several micrometers can be produced in approximately 10 hr.

The substrate 2 must be heat resistant to a certain degree for heating, and the surface is desirably flat. Examples of usable materials include glass sheet, silicon (Si) sheet, synthetic resin film such as polyimide and the like. If synthetic resin film is used as the substrate 2, the material can be easily cut later.

Examples of usable salts of metallic aluminates (HxAlyO2) foremost of which are alkali earth metals such as strontium (Sr), calcium (Ca) and the like, and oxides of rare earth elements such as europium (Eu), dysprosium (Dy), neodymium and the like may be used. Europium is an activator which absorbs light energy, and dysprosium and neodymium are coactivators which participate in the release of energy as light, and maintain light emission for a long period.

The raw material of the target 4 need not be uniformly mixed insofar as the ratio of the surface area of the raw material is fixed. That is, the form of the raw material may be either granular or powder, bulk or sheet. For example, the target 4 may be a mixture of aluminate powder and rare earth element powder approximately uniformly dispersed, target 4 having pellets of rare earth element placed on an aluminate sheet, a target 4 having pellets of rare earth element placed on aluminate powder may be used as raw materials.

Since atoms, atom groups and the like become airborne from the raw material through spattering and accumulate via their small size regardless of the shape of the raw material, the obtained thin film has high degree of transparency virtually without air gaps. Furthermore, since atoms, atom groups and the like are deposited at random positions even when the raw material is not uniform, the obtained thin later has uniform composition.

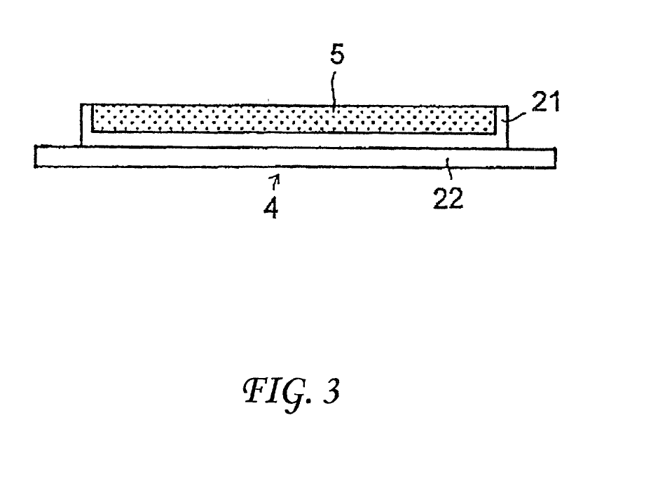

An example of a target 4 when aluminate powder and rare earth element powder are mixed is shown in FIG. 3. A glass laboratory dish 21 is anchored to a backing plate 22, and mixed powder 5 is introduced to the dish 21 and this dish is used as the target 4. A method using raw material in this form is known as a powder method.

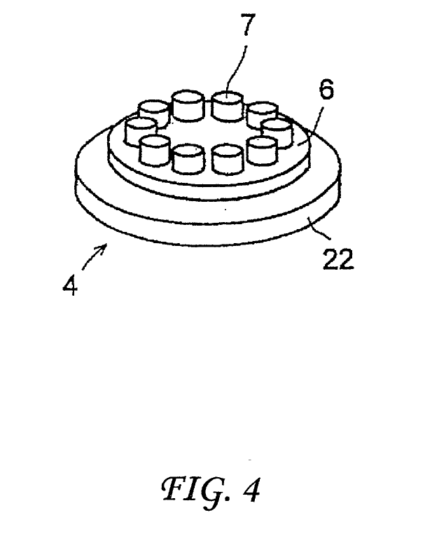

An example of a target 4 when pellets of rare earth element are placed on an aluminate sheet is shown in FIG. 4. An aluminate sheet 6 is directly anchored to a backing plate 22, and pellets 7 are placed thereon. A method using raw material in this form is known as a pellet method.

In any of these methods the percentage of raw material must be set beforehand to obtain a thin film of desired composition. In the powder method, the relative amounts of raw materials can be adjusted before becoming the mixed powder 5. In the pellet method, the percentage can be adjusted by the number of pellets 7 and the size of the pellets 7 relative to the sheet 6. When two or more types of rare earth element are included in the thin film 1, the relative amounts of the two or more types of rare earth element compounds included in the mixed powder 5 may be adjusted, and the number and relative size of the pellets 7 of the two or more types of rare earth element compounds may be adjusted.

Since spattering conditions differ depending on the types of constituents and gas, and components may revaporize from a once-formed thin film, the percentage of raw material may not match the composition of the produced thin film 1, such that the raw material percentages should be set beforehand in consideration of the type of raw material and the spattering method.

When argon (Ar) is used as the spattering gas, spattering efficiency is efficient, and the film forming speed is high. However, when only argon is used as the spattering gas, the oxygen in the produced thin film may not attain a desired composition depending on the raw material. In this case, oxygen (O2), and ozone (O3) may be added to argon and used as the spattering gas. For this reason, the RF magnetron spattering device 10 is provided with pipes 16 and 17 to supply two spattering gases. Argon gas is supplied from the pipe 16, and oxygen gas, or oxygen gas including ozone is supplied from the pipe 17 as necessary.

The oxygen and ozone included in the spattering gas desirably has a concentration of 5% or more but less than 50%. When the oxygen and ozone is less that 5%, the oxygen insufficiency prevents adequate effect being attained, and conversely, when the concentration exceeds 50%, there is too little argon gas, and spattering efficiency is reduced, and a long time is required to form the film.

The temperature of the substrate 2 during film formation may be determined in accordance with the heat resistance of the substrate 2 and the components of the thin film 1 being produced, however, a temperature in a range of 200˜700° C. is suitable. Setting the temperature of the substrate 2 at 200° C. or higher induces atoms and atom groups to deposit in well formed crystals, so as to greatly increase load density and transparency of the obtained thin film. Setting the substrate 2 temperature at less than 700° C. avoids much of the revaporization of the once-deposited components.

### EXAMPLE 1

In this example, a powder method was used using SrAl₂O₄ and Eu₂O₃ and Dy₂O₃ as raw materials. Specifically, 94 mol % SrAl₂O₄ powder, 5 mol % Eu₂O₃ powder, and 1 mol % Dy₂O₃ powder were thoroughly mixed, and the mixed powder was introduced into a glass laboratory dish 21 anchored to a backing plate 22, ethanol was added and the mixture was hardened by kneading, then the ethanol was removed by baking for 3 hr in an oven set at 60° C. to obtain a target 4. The addition of ethanol hardens the raw material and prevents airborne dispersion as a powder; ethanol does not participate in RF magnetron spattering. Other organic solvent, and water also may be used in place of the ethanol.

A glass plate having a surface polished to a mirror surface was used as the substrate 2. The laboratory dish 21 was circular with a diameter of approximately 80 mm, the substrate 2 was square with a side of approximately 20 mm, and thickness of 0.4 mm. The film forming conditions are shown in Table 1.

TABLE 1

| | |
|---|---|
| Substrate temperature | 350° C. |
| Attained vacuum | 1.33 × 10⁻⁴ Pa (1 × 10⁻⁶ Torr) |
| Spatter gas | Ar (70 mol %) + O2 (30 mol %) |
| Discharge vacuum | 6.67 × 10⁻¹ Pa (5 × 10⁻³ Torr) |
| RF power | 300 W |
| RF frequency | 13.56 MHz |
| Film forming speed | 0.5 μm/hr |
| Film thickness | 3 μm |

The light-accumulation optical element 3 obtained in this example was designated specimen S1. The composition of the thin film 1 of the specimen S1 was examined by the EPMA (electron probe X-ray micro analysis) method for each of several tens of randomly selected minute areas (i.e., squares approximately 20 μm on edge) with the result that all areas included Eu and Dy, and it was confirmed that there was no difference in the composition ratios of Sr, Al, O, Eu, Dy among the areas.

### EXAMPLE 2

In example 2, argon alone was use as the spatter gas, while other conditions were completely identical with those of example 1. The light-accumulating optical element 3 obtained in this example was designated specimen S2. The composition of the thin film 1 of the specimen S2 was examined by the EPMA method for each of several tens of areas with the result that all areas included Eu and Dy, and although it was confirmed that there was no difference in the composition ratios of Sr, Al, O, Eu, Dy among the areas, the amount of oxygen was several percent less than in the specimen s1.

### REFERENCE EXAMPLE 1

Reference example 1 produced a thin film by a vacuum deposition method, not the RF magnetron spattering method. A mixture of 94 mol % SrAl₂O₄ powder, 5 mol % Eu₂O₃ powder, and 1 mol % Dy₂O₃ powder was thoroughly mixed. The raw material and composition of example 3 was identical that of example 1 and example 2. The substrate was also identical to that used in example 1 and example 2. Film forming conditions are shown in Table 2.

### Table 2

| | |
|---|---|
| Substrate temperature | 350° C. |
| Attained vacuum | 1.33 × 10⁻⁴ Pa (1 × 10⁻⁶ Torr) |
| Vaporization source | Electron beam heating |
| Crucible | Copper |
| Film forming vacuum | 6.67 × 10⁻⁴ Pa (5 × 10⁻⁶ Torr) |
| (oxygen atmosphere) | |
| Film forming speed | 0.7 μm/hr |
| Film thickness | 3 μm |

The specimen obtained in this example was designated R1. The composition of the thin film 1 of the specimen R1 was examined by the EPMA method, and nearly all areas did not include Eu and Dy, and those areas that did include Eu and Dy were in trace amount only.

### REFERENCE EXAMPLE 2

Reference example 2 produced a light-accumulating ceramic by a conventional method. A mixture of 94 mol % SrAl₂O₄ powder, 5 mol % Eu₂O₃ powder, and 1 mol % Dy₂O₃ powder was used as raw material. The composition and raw material of this example was identical that of example 1 and example 2. Each powder was thoroughly mixed, sintered for 5 hr at 1000° C., and thereafter pulverized and repowdered and subjected to pressure to obtain a thin sheet approximately 100 μm in thickness.

The light-accumulating ceramic obtained in this example was designated specimen R2. The composition of the specimen R2 was examined by the EPMA method, and areas that did not include Eu and Dy, and areas that did included Eu and Dy in quantities several fold greater than the raw material composition were confirmed.

Emission Test 1

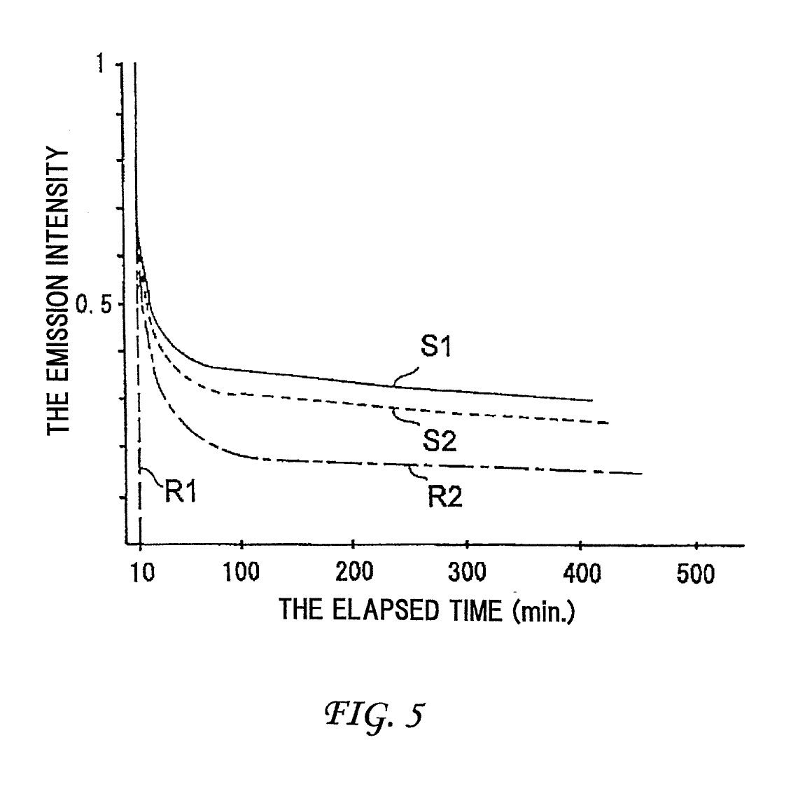

The results of emissions tests performed using specimens S1 and S2 of the examples, and specimens R1 and R2 of the reference examples are shown in FIG. 5. A black light (wavelength: 365 nm; 15 W) was used as the light source for light accumulation, and emission intensity measurement was started directly after irradiation for 10 min in a dark box. The horizontal axis in FIG. 5 represents the elapsed time from the start of irradiation, and the vertical axis represents the relative intensity using the emission intensity directly after the end of irradiation as a standard.

The specimen R2 of the reference example exhibited the typical emission characteristics of a light-accumulation ceramic. That is, although the emission intensity was approximately 20% lower in several tens of minutes, the emission continued at that intensity for several hundreds of minutes or longer. The specimen R1 of the reference example 1 did not exhibit light accumulation phenomenon at all.

On the other hand, the specimen S2 of example 2 exhibited a higher emission intensity than specimen R2 of the reference example, and the emission intensity was approximately 30% even after several hundred minutes elapsed. The specimen S1 of example 1 exhibited the highest emission intensity. The intensity was approximately 35% after several tens of minutes had elapsed, and emission at this intensity was maintained and continued for more than several hundreds of minutes.

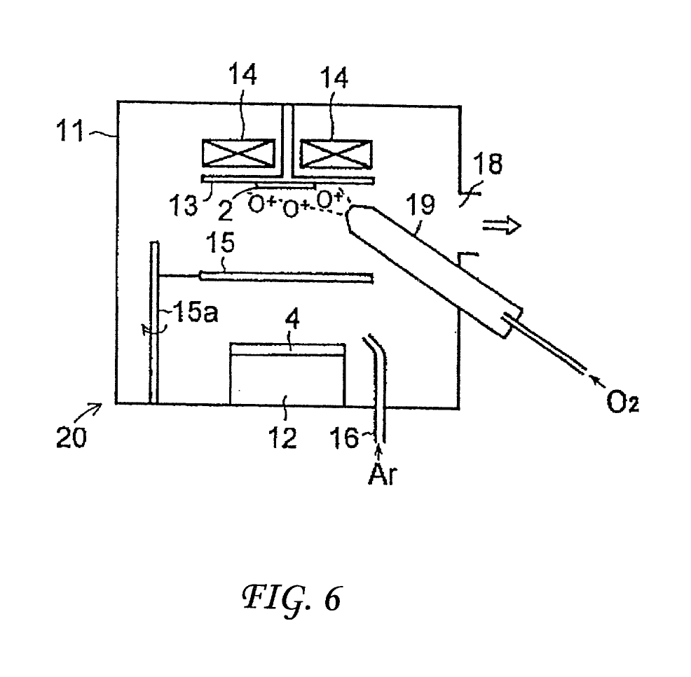

A second embodiment is described below. This embodiment performs RF magnetron spattering using only argon gas as a spatter gas while supplying oxygen ions near the substrate 2. The structure of a RF magnetron spattering device 20 used in this embodiment is briefly shown in FIG. 6. The RF magnetron spattering device 20 provides an ion gun 19 and eliminates the oxygen supply pipe 17 of the device 10 used in the first embodiment. The ion gun 19 is positioned near the substrate holder 13, and ionizes oxygen and supplies the oxygen ions to the surface of the substrate 2.

Spattering efficiency is increased and film forming speed is increased by using only argon gas as the spatter gas. Furthermore, since oxygen accumulates together with atoms and atom groups generated by spattering, the thin film 1 avoids an oxygen insufficiency. Oxygen including ozone may be ionized and supplied rather than ionizing oxygen alone.

### EXAMPLE 3

In this example, a powder method was used and CaAl₂O₄, Eu₂O₃, and Nd₂O₃ were used as raw materials. Specifically, 95 mol % CaAl₂O₄ powder, 3 mol % Eu₂O₃ powder, and 2 mol % Nd₂O₃ powder were thoroughly mixed, and ethanol was added into a glass laboratory dish 21 and the mixture was hardened by kneading, then the ethanol was removed by baking for 3 hr in an oven set at 60° C. to obtain a target 4. A polyimide film was used as the substrate 2. The laboratory dish 21 was circular with a diameter of approximately 80 mm, the substrate 2 was square with a side of approximately 20 mm, and thickness of 20 μm. The film forming conditions are shown in Table 3.

TABLE 3

| | |
|---|---|
| Substrate temperature | 250° C. |
| Attained vacuum | 6.67 × 10⁻⁵ Pa (1 × 10⁻⁷ Torr) |
| Spatter gas | Ar |
| Discharge vacuum | 6.67 × 10⁻¹ Pa (5 × 10⁻³ Torr) |
| RF power | 300 W |
| RF frequency | 13.56 MHz |
| Film forming speed | 0.8 μm/hr |
| Film thickness | 3 μm |

The light-accumulation optical element 3 obtained in this example was designated specimen S3. The composition of the thin film 1 of the specimen S3 was examined by the EPMA method for each of several tens of areas with the result that all areas included Eu and Nd, and it was confirmed that there was no difference in the composition ratios of Ca, Al, O, Eu, Nd among the areas. Furthermore, the ratio of CaAl₂O₄:Eu:Nd was confirmed to be identical with the ratio of raw material composition of 95:3:2.

### EXAMPLE 4

Example 4 performed spattering without supplying oxygen ion and oxygen from the ion gun 19, but in other conditions were identical to example 3. The light-accumulation optical element 3 obtained in this example was designated specimen S4. The composition of the thin film 1 of the specimen S4 was examined by the EPMA method for each of several tens of areas with the result that all areas included Eu and Nd, and although it was confirmed that there was no difference in the composition ratios of Ca, Al, O, Eu, Nd among the areas, the amount of oxygen was several percent less than in the specimen S3. That is, the results were identical to the relationship of example 2 to example 1.

### REFERENCE EXAMPLE 3

Reference example 3 produced a light-accumulating ceramic by a conventional method. A mixture of 95 mol % CaAl₂O₄ powder, 3 mol % Eu₂O₃ powder, and 2 mol % Nd₂O₃ powder was used as raw material. The composition and raw material of this example was identical that of example 3 and example 4. Each powder was thoroughly mixed, sintered for 5 hr at 1000° C., and thereafter pulverized and repowdered and subjected to pressure to obtain a thin sheet approximately 100 μm in thickness.

The light-accumulating ceramic obtained in this example was designated specimen R3. The composition of the specimen R3 was examined by the EPMA method, and areas that did not include any Eu and Nd, and areas that did included Eu and Dy in quantities several fold greater than the raw material composition were confirmed.

Emission test 2

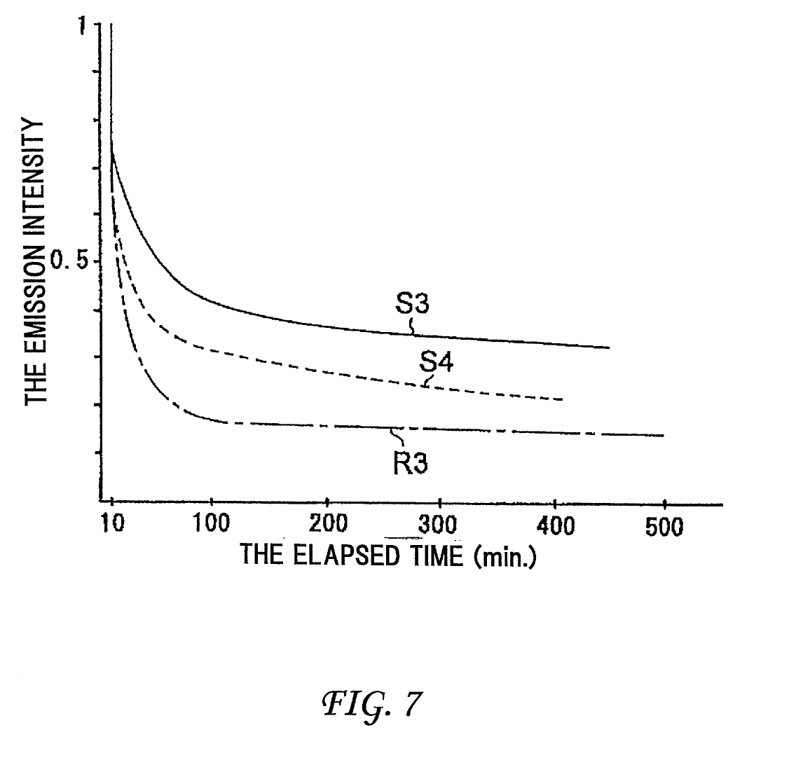

The results of emissions tests performed using specimens S3 and S4 of the examples, and specimen R3 of the reference example are shown in FIG. 7. Sunlight was used as the light source for light accumulation. Emission intensity measurement was started when the specimen was placed in a dark box directly after irradiation for 10 min in the sunlight. The horizontal axis in FIG. 7 represents the elapsed time from the start of irradiation, and the vertical axis represents the relative intensity using the emission intensity directly after the end of irradiation as a standard.

The specimen R3 of the reference example exhibited the typical emission characteristics of a light-accumulation ceramic. The specimen S4 of example 4 exhibited a higher emission intensity than specimen R3 of the reference example, and specimen S3 of example 3 exhibited a higher emission intensity than specimen S4. The intensity after 400 minutes had elapsed was approximately 15% for the specimen R3, approximately 20% for the specimen S4, and approximately 35% for the specimen S3.

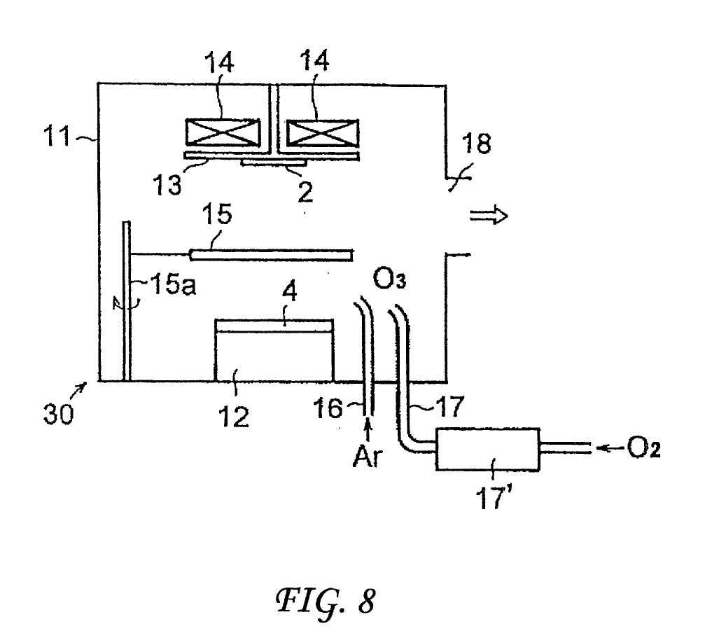

A third embodiment is described below. This embodiment includes ions in the oxygen gas (O2) supplied as the spatter gas to the first embodiment. The structure of an RF magnetron spattering device 30 used in this embodiment is briefly shown in FIG. 8. The RF magnetron spattering device 30 is provided with an ozone generator 17′ mounted on the pipe 17 of the device 10 used in the first embodiment. A reduction in spattering efficiency was avoided and film forming speed improved by adding ozone having a higher activity than oxygen to the spatter gas.

### EXAMPLE 5

In this example, a powder method was used using Sr₄Al₁₄O₂₅ and Eu₂O₃ and Nd₂O₃ as raw materials. Specifically, 95 mol % Sr₄Al₁₄O₂₅ powder, 3 mol % Eu₂O₃ powder, and 2 mol % Nd₂O₃ powder were thoroughly mixed, ethanol was added into the laboratory dish 21, the mixture was hardened by kneading, then the ethanol was removed by baking for 3 hr in an oven set at 60° C. to obtain a target 4. A sheet of silicon monocrystal having a surface polished to a mirror surface was used as the substrate 2. The laboratory dish 21 was circular with a diameter of approximately 80 mm, the substrate 2 was square with a side of approximately 20 mm, and thickness of 0.4 mm. The film forming conditions are shown in Table 4.

TABLE 4

| | |
|---|---|
| Substrate temperature | 500° C. |
| Attained vacuum | 6.67 × 10⁻⁵ Pa (1 × 10⁻⁷ Torr) |
| Spatter gas | Ar (90 mol %) + O2 + O3 (10 mol %) |
| Discharge vacuum | 6.67 × 10⁻¹ Pa (5 × 10⁻³ Torr) |
| RF power | 300 W |
| RF frequency | 13.56 MHz |
| Film forming speed | 0.75 μm/hr |
| Film thickness | 2 μm |

The light-accumulation optical element 3 obtained in this example was designated specimen S5. The composition of the thin film 1 of the specimen S5 was examined by the EPMA method with the result that all of several tens of areas included Eu and Nd, and it was confirmed that there was no difference in the composition ratios of Sr, Al, O, Eu, Dy among the areas. Furthermore, the ratio of Sr₄Al₁₄O₂₅:Eu:Nd was confirmed to be identical with the ratio of raw material composition of 95:3:2.

### EXAMPLE 6

Example 6 performed spattering using only argon gas as the spatter gas, but in other conditions were identical to example 5. The light-accumulation optical element 3 obtained in this example was designated specimen S6. The composition of the thin film 1 of the specimen S6 was examined by the EPMA method for each of several tens of areas with the result that all areas included Eu and Nd, and although it was confirmed that there was no difference in the composition ratios of Sr, Al, O, Eu, Nd among the areas, the amount of oxygen was several percent less than in the specimen S5.

### REFERENCE EXAMPLE 4

Reference example 4 produced a light-accumulating ceramic by a conventional method. A mixture of 95 mol % Sr₄Al₁₄O₂₅ powder, 3 mol % Eu₂O₃ powder, and 2 mol % Nd₂O₃ powder was used as raw material. The composition and raw material of this example was identical that of example 5 and example 6. Each powder was thoroughly mixed, sintered for 5 hr at 1000° C., and thereafter pulverized and repowdered and subjected to pressure to obtain a thin sheet approximately 100 μm in thickness.

The light-accumulating ceramic obtained in this example was designated specimen R4. The composition of the specimen R4 was examined by the EPMA method, and areas that did not include any Eu and Nd, and areas that did included Eu and Dy in quantities several fold greater than the raw material composition were confirmed, similar to reference example 2 and reference example 4.

Emission Test 3

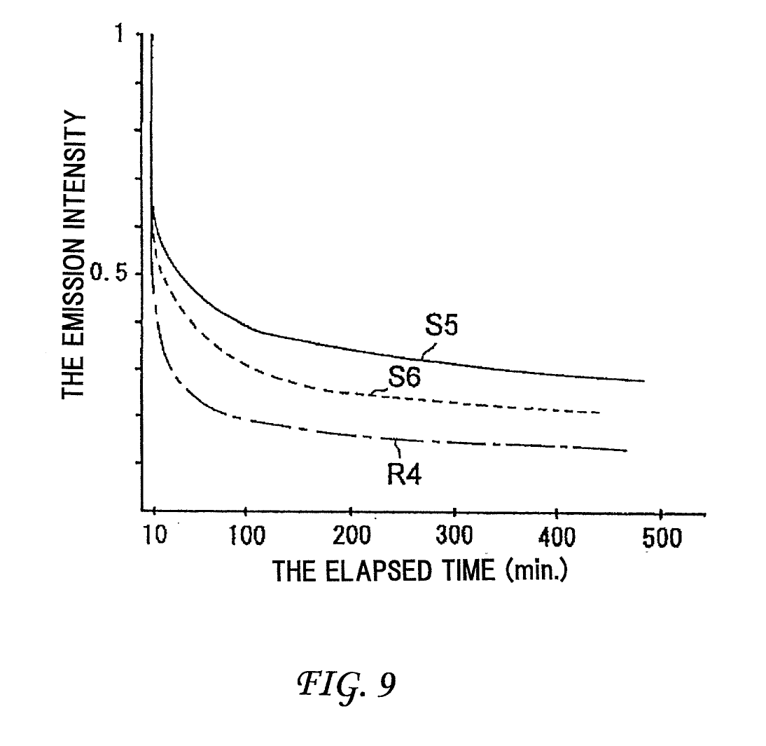

The results of emissions tests performed using specimens S5 and S6 of the examples, and specimen R4 of the reference example are shown in FIG. 9. A fluorescent light (20 W) was used as the light source for light accumulation. Emission intensity measurement was started directly after irradiation for 10 min in a dark box. The horizontal axis in FIG. 9 represents the elapsed time from the start of irradiation, and the vertical axis represents the relative intensity using the emission intensity directly after the end of irradiation as a standard.

The specimen R4 of the reference example exhibited the typical emission characteristics of a light-accumulation ceramic. The specimen S6 of example 6 exhibited a higher emission intensity than specimen R4 of the reference example, and specimen S5 of example 5 exhibited a higher emission intensity than specimen S6. The intensity after 400 minutes had elapsed was approximately 15% for the specimen R4, approximately 20% for the specimen S6, and approximately 35% for the specimen S5.

A fourth embodiment is described below. This embodiment produces a primary body of a light-accumulation optical element by RF magnetron spattering using only argon as the spatter gas, and the obtained primary body is heated in the presence of oxygen gas to obtain a light-accumulation element 3. Oxygen insufficiency in the thin film is supplemented by heating in the presence of oxygen.

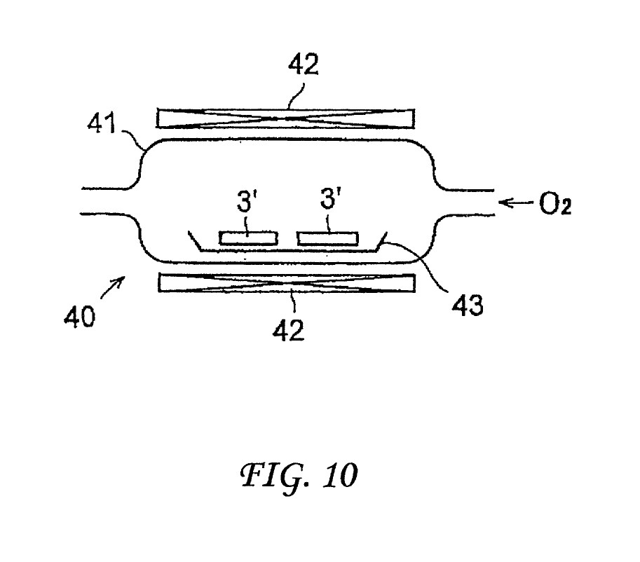

The structure of an annealing device 40 used to heat the primary body is briefly shown in FIG. 10. The annealing device 40 is provided with a glass tube 41 which is thin at its bilateral ends, and a heater 42 which surrounds the glass tube 41. The primary body 3′ of the light-accumulation optical element 3 is loaded on a glass boat 43, and housed in the glass tube 41. The heater 42 heats as oxygen flows in from the end of the glass tube 41, and the amount of oxygen content of the thin film is increased on the primary body 3′. At this time, a thermocouple is mounted beforehand on the substrate of the primary body 3′ to monitor the temperature.

The temperature may be in a range of 300˜500° C. When the temperature is 300° C. or higher, adequate oxygen is taken in the thin film of the primary body 3′. When the temperature is less than 500° C., revaporization of the components of the thin film is avoided, and synthetic resin film which has a relatively low heat resistance can be used as the substrate 2.

### EXAMPLE 7

RF magnetron spattering was performed by a pellet method using CaAl₂O₄, Eu₂O₃, and Nd₂O₃ as raw materials. A sintered plate of CaAl₂O₄ was circular with a diameter of 75 mm, and thickness of 5 mm. Pellets of Eu₂O₃, and Nd₂O₃ were all cylinders 5 mm in diameter and 3 mm high. As shown in FIG. 4, a CaAl₂O₄ sintered plate is anchored to a backing plate 22, and six Eu₂O₃ pellets 7 and four Nd₂O₃ pellets 7 are placed thereon in a circle to form the target 4. The percentage of surface area of each raw material as a percentage of the total surface area of the substrate 2 is 95.55%, 2.67%, and 1.78%; since the sides of the pellets are also exposed, the composition of the raw materials CaAl₂O₄, Eu₂O₃, and Nd₂O₃ is generally 95 mol %, 3 mol %, 2 mol %, respectively.

A square polyimide film measuring approximately 20 mm on edge and 20 μm in thickness was used as the substrate similar to example 3. The RF magnetron spattering was also performed under the same conditions as in example 3.

The obtained primary body 3′ was placed in the annealing device 40, and heated for 4 hr at 300° C. to obtain the light-accumulation optical element 3. This light-accumulation optical element 3 was designated specimen S7. When the specimen S7 was examined by the EPMA method, it was confirmed that each of several tens of areas included Eu and Nd, and there was no difference in the composition ratios of CA, Al, O, Eu, Nd among the areas. The ratio of CaAl₂O₄:Eu₂O₃:Nd₂O₃ was generally 95:3:2. In an emission test under conditions identical to the emission test 2, specimen S7 exhibited a high emission intensity similar to specimen S3.

### EXAMPLE 8

In this example, the specimen S2 obtained in example 2 was used as the primary body 3′, and this primary body 3′ was placed in the annealing device 40 and heated for 2 hr at 400° C. to obtain a light-accumulation optical element 3. This light-accumulation optical element 3 was designated specimen S8. When the thin film 1 of specimen S8 was examined by EPMA method, it was confirmed that the amount of oxygen was increased, and the composition was near identical to that of specimen S1 of example 1. In an emission test under conditions identical to the emission test 1, specimen S8 exhibited a high emission intensity similar to specimen S1.

RF magnetron spattering with oxygen and ozone added to the spatter gas (first and third embodiments), RF magnetron spattering while supplying oxygen ion near the substrate (second embodiment), and heating in the presence of oxygen after forming the film (fourth embodiment) may be used in combinations of two or three methods. Although the structure of the devices used in the embodiments of the present invention have been described, these are only examples, and other structures also may be used. The positional relationship of the raw material and substrate are not limited to the former below and the latter above, inasmuch as RF magnetron spattering may be performed with the raw material anchored to the cathode so as to prevent falling, and the raw material may be placed above and the substrate placed below, or the raw material and substrate may be placed in horizontal directions.

The thin film of the present invention differs from ceramic, and characteristically has no air gaps, is highly transparent, and has uniform composition. Therefore, the thin film is capable of absorbing light energy throughout the entirety of the film, and light-accumulation efficiency is excellent. Furthermore, emitted light is not subject to random reflection within the thin film. Accordingly, the light accumulation material has a high emission intensity.

The light-accumulation optical element of the present invention is easy to manufacture since it uses a thin film as a light-accumulation material, has a high emission intensity, and the thin film is supported by a substrate. If the substrate is transparent, the element can receive light from the substrate side and emit light to the substrate side.

A thin film having high emission intensity suitable for light-accumulation material can be easily obtained by the method of the present invention. The concentration of rare earth elements also can be freely adjusted.

In particular, a thin film without oxygen insufficiency can be efficiently manufactured by argon gas spattering while supplying oxygen or ozone or oxygen and ozone near the substrate.

Although the present invention has been fully described by way of examples with reference to the accompanying drawings, it is to be noted that various changes and modifications will be apparent to those skilled in the art. Therefore, unless otherwise such changes and modifications depart from the scope of the present invention, they should be construed as being included therein.

What is claimed is:

1. A thin film essentially comprising aluminate as primary component and rare earth element.

2. A thin film according to claim 1, which essentially consists of the aluminate and the rare earth element.

3. A thin film according to claim 1, wherein the aluminate is selected form the group consisting of SrAl₂O₄, Sr₄Al₁₄O₂₅ and CaAl₂O₄, and
the rare earth element contains either Dy or Nd and Eu.

4. A light-accumulation optical element comprising:
a thin film which comprises aluminate as primary component and rare earth element; and
a substrate which supports the thin film.

5. A light accumulation optical element according to claim 4, wherein the thin film essentially consists of the aluminate and the rare earth element.

6. A method for producing a light-accumulation optical element according to claim 5, the method comprising the steps of:
providing a raw material including aluminate and rare earth element on a magnetron cathode;
placing a substrate opposite the raw material; and
moving the raw material component onto the substrate via RF magnetron spattering.

7. A method according to claim 6, wherein the raw materials comprising:
an aluminate selected form a group consisting of SrAl₂O₄, Sr₄Al₁₄O₂₅, and CaAl₂O₄;
Dy₂O₃ or Nd₂O₃; and
Eu₂O₃.

8. A method according to claim 6, wherein the raw material comprises a mixture of aluminate powder and rare earth element powder.

9. A method according to claim 6, wherein the raw material comprises a sintered plate of aluminate and pellets of rare earth element compound.

10. A method according to claim 6, wherein
a temperature of the substrate is maintained a range of 200° C. or higher but lower than 700° C. while the RF magnetron spattering is performed.

11. A method according to claim 6, wherein
the RF magnetron spattering is performed using argon gas containing 5% or more, but less than 50% oxygen or ozone.

12. A method according to claim 6, wherein
the RF magnetron spattering is performed using argon gas and supplying oxygen or ozone or ions thereof near the substrate.

13. A method according to claim 12, wherein the argon gas comprises either oxygen or ozone.

14. A method according to claim 13, further comprising the step of heating the thin film on the substrate after the RF magnetron spattering is performed.
